(19) United States
(12) Patent Application Publication
(10) Pub. No.: US 2018/0287613 A1
(43) Pub. Date: Oct. 4, 2018

(54) SEMICONDUCTOR DEVICE, METHOD OF OPERATING A SEMICONDUCTOR DEVICE, AND SYSTEM INCLUDING THE SAME

(71) Applicant: SK hynix Inc., Icheon-si Gyeonggi-do (KR)

(72) Inventor: Ki Won LEE, Icheon-si Gyeonggi-do (KR)

(73) Assignee: SK hynix Inc., Icheon-si Gyeonggi-do (KR)

(21) Appl. No.: 15/844,060

(22) Filed: Dec. 15, 2017

(30) Foreign Application Priority Data
Apr. 4, 2017 (KR) 10-2017-0043565

(51) Int. Cl. H03K 19/0185

(52) U.S. Cl. CPC H03K 19/018521

(57) ABSTRACT

A semiconductor device may be provided. The semiconductor device may include a first input signal-inverting circuit, a second input signal-inverting circuit, a first level-shifting circuit and a second level-shifting circuit. The first input signal-inverting circuit may be configured to invert and output an input signal. The second input signal-inverting circuit may be configured to invert and output an output signal from the first input signal-inverting circuit. The first level-shifting circuit may be configured to determine a voltage level of a first output node in response to the output signals from the first and second input signal-inverting circuits. The second level-shifting circuit may be configured to determine a voltage level of a second output node in response to the output signals from the first and second input signal-inverting circuits.

### CROSS-REFERENCES TO RELATED APPLICATION

The present application claims priority under 35 U.S.C. § 119(a) to Korean application number 10-2017-0043565, filed on Apr. 4, 2017, in the Korean Intellectual Property Office, which is incorporated herein by reference in its entirety.

### BACKGROUND

### 1. Technical Field

Various embodiments generally relate to a semiconductor integrated circuit, more particularly to a semiconductor device and method of operating the semiconductor device.

### 2. Related Art

A semiconductor device may be configured to receive signals from an external device. Further, the semiconductor device may be configured to transmit signals between an internal circuit and an external circuit in the semiconductor device.

When the semiconductor device transmits or receives the signals, it may be required to change a maximum voltage level and a minimum voltage level of the signals.

Therefore, a circuit configured to stably vary the maximum voltage level and the minimum voltage level of the signal may be required.

### SUMMARY

In an embodiment, a semiconductor device may be provided. The semiconductor device may include a first input signal-inverting circuit, a second input signal-inverting circuit, a first level-shifting circuit and a second level-shifting circuit. The first input signal-inverting circuit may be configured to invert and output an input signal. The second input signal-inverting circuit may be configured to invert and output an output signal from the first input signal-inverting circuit. The first level-shifting circuit may be configured to determine a voltage level of a first output node in response to the output signals from the first and second input signal-inverting circuits. The second level-shifting circuit may be configured to determine a voltage level of a second output node in response to the output signals from the first and second input signal-inverting circuits.

In an embodiment, a method of operating a semiconductor device may be provided. The method may include inverting a first input signal and outputting a first resultant signal. The method may include inverting the resultant signal and outputting a second resultant signal. The method may include determining a voltage level of a first output node in response to the first and second resultant signals. The method may include determining a voltage level of a second output node in response to the first and second resultant signals.

### BRIEF DESCRIPTION OF THE DRAWINGS

FIG. 1 is a circuit diagram illustrating a semiconductor device in accordance with example embodiments; and

FIG. 2 is a circuit diagram illustrating a semiconductor device in accordance with example embodiments.

FIG. 3 illustrates a block diagram of an example of a representation of a system employing a semiconductor device and or method of operating the same with the various embodiments discussed above with relation to FIGS. 1-2.

### DETAILED DESCRIPTION

Hereinafter, examples of embodiments will be described below with reference to the accompanying drawings through various examples of embodiments.

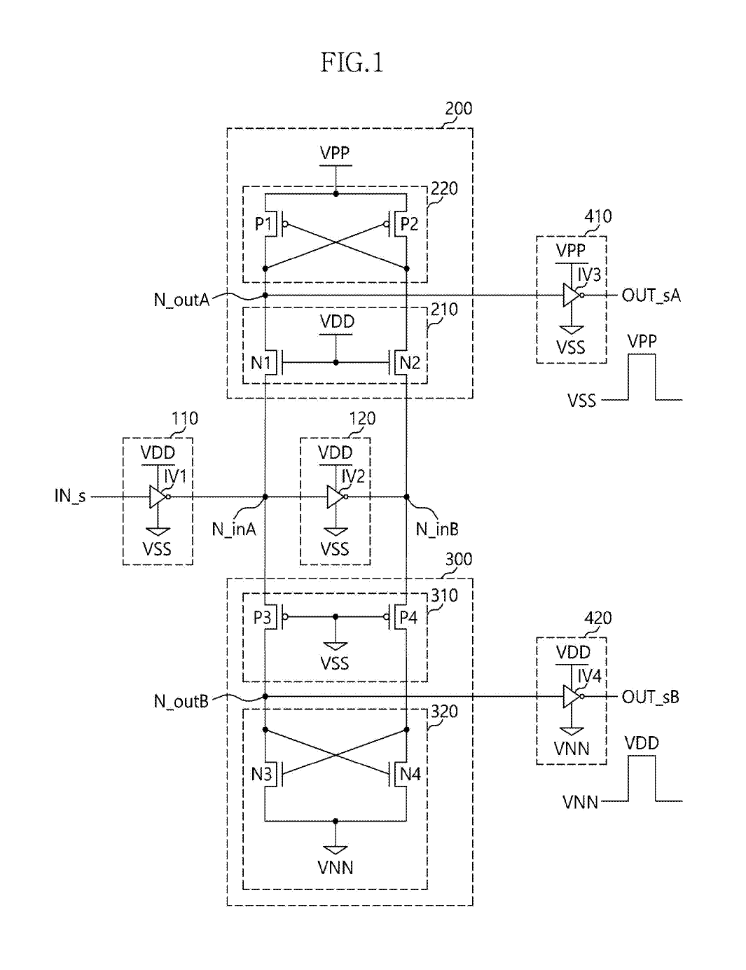

FIG. 1 is a circuit diagram illustrating a semiconductor device in accordance with an example of an embodiment.

Referring to FIG. 1, a semiconductor device according to an example of an embodiment may include a first input signal-inverting circuit 110, a second input signal-inverting circuit 120, a first level-shifting circuit 200, a second level-shifting circuit 300, a first output circuit 410 and a second output circuit 420.

The first input signal-inverting circuit 110 may invert an input signal IN_s. The first input signal-inverting circuit 110 may output the inverted input signal IN_s to a first input node N_inA.

The first input signal-inverting circuit 110 may include a first inverter IV1. The first inverter IV1 may receive an external voltage VDD and a ground voltage VSS. Thus, a maximum voltage level of the output signal from the first inverter IV1 may correspond to the s external voltage VDD. A minimum voltage level of the output signal from the first inverter IV1 may correspond to the ground voltage VSS.

The second input signal-inverting circuit 120 may invert the output signal from the first input signal-inverting circuit 110. The second input signal-inverting circuit 120 may output the inverted output signal to a second input node N_inB.

The second input signal-inverting circuit 120 may include a second inverter IV2. The second inverter IV2 may receive the external voltage VDD and the ground voltage VSS. Thus, a maximum voltage level of the output signal from the second inverter IV2 may correspond to the external voltage VDD. A minimum voltage level of the output signal from the second inverter IV2 may correspond to the ground voltage VSS.

The first level-shifting circuit 200 may be configured to determine a voltage level of a first output node N_outA in response to the voltage levels of the first and second input nodes N_inA and N_inB. The first level-shifting circuit 200 may receive a pumping voltage VPP. The first level-shifting circuit 200 may be operated by the pumping voltage VPP. For example, when the voltage level of the first input node N_inA is at the external voltage VDD level and the voltage level of the second input node N_inB is at the ground voltage VSS level, the first level-shifting circuit 200 may increase the voltage level of the first output node N_outA to the pumping voltage VPP. In contrast, when the voltage level of the first input node N_inA may be the ground voltage VSS and the voltage level of the second input node N_inB may be the external voltage VDD, the first level-shifting circuit 200 may provide the voltage level of the first output node N_outA with the ground voltage VSS.

The first level-shifting circuit 200 may include a first signal transmission circuit 210 and a first latch circuit 220.

The first signal transmission circuit 210 may transmit any one of the voltage levels of the first and second input nodes N_inA and N_inB to the first latch circuit 220 in response to the voltage levels of the first and second input nodes N_inA and N_inB. For example, the first signal transmission circuit 210 may transmit a voltage of an input node having a relatively low voltage level among the voltage levels of the first and second input nodes N_inA and N_inB to the first latch circuit 220. Particularly, when the voltage level of the first input node N_inA is at the external voltage VDD level and the voltage level of the second input node N_inB is at the ground voltage VSS level, the first signal transmission circuit 210 may transmit the voltage level of the first input node N_intA to the first latch circuit 220. In contrast, when the voltage level of the first input node N_inA is at the ground voltage VSS and the voltage level of the second input node N_inB is at the external voltage VDD, the first signal transmission circuit 210 may transmit the voltage level of the second input node N_inB to the first latch circuit 220.

The first signal transmission circuit 210 may include a first transistor N1 and a second transistor N2. The first transistor N1 may include a gate to which the external voltage VDD may be applied, a source connected with the first input node N_inA, and a drain connected with the first latch circuit 220. The second transistor N2 may include a gate to which the external voltage VDD may be applied, a source connected with the second input node N_inB, and a drain connected with the first latch circuit 220.

The first latch circuit 220 may be configured to determine the voltage level of the first output node N_outA in response to any one of the voltage levels of the first and second input nodes N_inA and N_inB transmitted from the first signal transmission circuit 210. For example, when the ground voltage VSS of the first input node N_inA is transmitted from the first signal transmission circuit 210, the first latch circuit 220 may provide the voltage level of the first output node N_outA with the ground voltage VSS. In contrast, when the ground voltage VSS of the second input node N_inB is transmitted from the first signal transmission circuit 210, the first latch circuit 220 may provide the voltage level of the first output node N_outA with the pumping voltage VPP.

The first latch circuit 220 may include a third transistor P1 and a fourth transistor P2. The third transistor P1 may include a gate connected with the second transistor N2 of the first signal transmission circuit 210, a source to which the pumping voltage VPP may be applied, and a drain connected with the first transistor N1 of the first signal transmission circuit 210. The fourth transistor P2 may include a gate connected with the first transistor N1 of the first signal transmission circuit 210, a source to which the pumping voltage VPP may be applied, and a drain connected with the second transistor N2 of the first signal transmission circuit 210.

The second level-shifting circuit 300 may be configured to determine a voltage level of a second output node N_outB in response to the voltage levels of the first and second input nodes N_inA and N_inB. The second level-shifting circuit 300 may receive a negative voltage VNN. The second level-shifting circuit 300 may be operated by the negative voltage VNN. For example, when the voltage level of the first input node N_inA is at the external voltage VDD level and the voltage level of the second input node N_inB is at the ground voltage VSS level, the second level-shifting circuit 300 may increase the voltage level of the second output node N_outB to the external voltage VDD. In contrast, when the voltage level of the first input node N_inA is at the ground voltage VSS level and the voltage level of the second input node N_inB is at the external voltage VDD level, the second level-shifting circuit 300 may decrease the voltage level of the second output node N_outB to the negative voltage VNN.

The second level-shifting circuit 300 may include a second signal transmission circuit 310 and a second latch circuit 320.

The second signal transmission circuit 310 may transmit any one of the voltage levels of the first and second input nodes N_inA and N_inB to the second latch circuit 320 in response to the voltage levels of the first and second input nodes N_inA and N_inB. For example, the second signal transmission circuit 310 may transmit a voltage of an input node having a relatively high voltage level among the voltage levels of the first and second input nodes N_inA and N_inB to the second latch circuit 320. Particularly, when the voltage level of the first input node N_inA is at the ground voltage VSS level and the voltage level of the second input node N_inB is at the external voltage VDD level, the second signal transmission circuit 310 may transmit the voltage level of the second input node N_inB to the second latch circuit 320. In contrast, when the voltage level of the first input node N_inA may be the external voltage VDD and the voltage level of the second input node N_inB may be the ground voltage VSS, the second signal transmission circuit 310 may transmit the voltage level of the first input node N_inA to the second latch circuit 320.

The second signal transmission circuit 310 may include a fifth transistor P3 and a sixth transistor P4. The fifth transistor P3 may include a gate to which the ground voltage VSS may be applied, a source connected with the first input node N_inA, and a drain connected with the second latch circuit 320. The sixth transistor P4 may include a gate to which the ground voltage VSS may be applied, a source connected with the second input node N_inB, and a drain connected with the second latch circuit 320.

The second latch circuit 320 may be configured to determine the voltage level of the second output node N_outB in response to any one of the voltage levels of the first and second input nodes N_inA and N_inB transmitted from the second signal transmission circuit 310. For example, when the external voltage VDD of the first input node N_inA is transmitted from the second signal transmission circuit 310, the second latch circuit 320 may provide the voltage level of the second output node N_outB with the external voltage VDD. In contrast, when the external voltage VDD of the second input node N_inB may be transmitted from the second signal transmission circuit 310, the second latch circuit 320 may provide the voltage level of the second output node N_outB with the negative voltage VNN.

The second latch circuit 320 may include a seventh transistor N3 and an eighth transistor N4. The seventh transistor N3 may include a gate connected with the sixth transistor P4 of the second signal transmission circuit 310, a source to which the negative voltage VNN may be applied, and a drain connected with the fifth transistor P3 of the second signal transmission circuit 310. The eighth transistor N4 may include a gate connected with the fifth transistor P3 of the second signal transmission circuit 310, a source to which the negative voltage VNN may be applied, and a drain connected with the sixth transistor P4 of the second signal transmission circuit 310.

The first output circuit 410 may output a first output signal OUT_sA in response to the voltage level of the first output node

N_outA. For example, when the voltage level of the first output node N_outA is at the voltage level of the ground voltage VSS, the first output circuit 410 may output the first output signal OUT_sA having the level of the pumping voltage VPP. In contrast, when the voltage level of the first output node N_outA is at the voltage level of the pumping voltage VPP, the first output circuit 410 may output the first output signal OUT_sA having the level of the ground voltage VSS.

The first output circuit 410 may include a third inverter IV3. The third inverter IV3 may invert the voltage level of the first output node N_outA to output the first output signal OUT_sA. The pumping voltage VPP and the ground voltage VSS may be applied to the third inverter IV3. Thus, the third inverter IV3 may be operated by the pumping voltage VPP and the ground voltage VSS.

The second output circuit 420 may output a second output signal OUT_sB in response to the voltage level of the second output node N_outB. For example, when the voltage level of the second output node N_outB is at the voltage level of the negative voltage VNN, the second output circuit 420 may output the second output signal OUT_sB having the level of the external voltage VDD. In contrast, when the voltage level of the second output node N_outB is at the voltage level of the external voltage VDD, the second output circuit 420 may output the second output signal OUT_sB having the level of the negative voltage VNN.

The second output circuit 420 may include a fourth inverter IV4. The fourth inverter IV4 may invert the voltage level of the second output node N_outB to output the second output signal OUT_sB. The external voltage VDD and the negative voltage VNN may be applied to the fourth inverter IV4. Thus, the fourth inverter IV4 may be operated by the external voltage VDD and the negative voltage VNN.

Hereinafter, operations of the semiconductor device in accordance with an example of an embodiment will be discussed below.

When the input signal IN_s is at a high level, the first input signal-inverting circuit 110 may output the output signal at the ground voltage VSS level. The second input signal-inverting circuit 120 may output the output signal of the first input signal-inverting circuit 110 at the external voltage VDD level. Thus, the first input node N_inA is at the ground voltage VSS level. The second input node N_inB is at the external voltage VDD level.

The first signal transmission circuit 210 may transmit the low voltage level of the input node among the first and second input nodes N_inA and N_inB to the first latch circuit 220. Therefore, the first signal transmission circuit 210 may transmit the voltage level of the first input node N_inA to the first latch circuit 220.

Particularly, the first signal transmission circuit 210 may include the first and second transistors N1 and N2. Because the external voltage VDD may be applied to the gates of the first and second transistors N1 and N2, turn-on of the first and second transistors N1 and N2 may be determined in accordance with the voltage level inputted into the sources. When the voltage level of the first input node N_inA is at the ground voltage VSS level and the voltage level of the second input node N_inB is at the external voltage VDD level, the first transistor N1 may be turned-on and the second transistor N2 may be turned-off. Thus, the voltage level of the first input node N_inA may be transmitted to the first latch circuit 220 through the turned-on first transistor N1.

When the first latch circuit 220 receives the ground voltage VSS level of the first input node N_inA, the fourth transistor P2 may be turned-on and the third transistor P1 may be turned-off. Thus, the first output node N_outA may be connected with the first input node N_inA so that the voltage level of the first output node N_outA may change to the ground voltage VSS level.

When the voltage level of the first output node N_outA changes to the ground voltage VSS level, the first output circuit 410 may output the first output signal OUT_sA having the pumping voltage VPP level.

As mentioned above, when the input signal IN_s is at the high level, the first input node N_inA may change to the ground voltage VSS level and the second input node N_inB may change to the external voltage VDD level.

The second signal transmission circuit 310 may transmit the high voltage level of the input node among the first and second input nodes N_inA and N_inB to the second latch circuit 320. Therefore, the second signal transmission circuit 310 may transmit the voltage level of the second input node N_inB to the second latch circuit 320.

Particularly, the second signal transmission circuit 310 may include the fifth and sixth transistors P3 and P4. Because the ground voltage VSS may be applied to the gates of the fifth and sixth transistors P3 and P4, turn-on of the fifth and sixth transistors P3 and P4 may be determined in accordance with the voltage level inputted into the sources. When the voltage level of the first input node N_inA is at the ground voltage VSS level and the voltage level of the second input node N_inB is at the external voltage VDD level, the sixth transistor P4 may be turned-on and the fifth transistor P3 may be turned-off. Thus, the voltage level of the second input node N_inB may be transmitted to the second latch circuit 320 through the turned-on sixth transistor P4.

When the second latch circuit 320 receives the external voltage VDD level of the second input node N_inB, the seventh transistor N3 may be turned-on so that the voltage level of the second output node N_outB may change to the negative voltage VNN level.

When the voltage level of the second output node N_outB changes to the negative voltage VNN level, the second output circuit 420 may output the second output signal OUT_sB having the external voltage VDD level.

When the input signal IN_s is at a low level, the first input signal-inverting circuit 110 may output the output signal at the external voltage VDD level. The second input signal-inverting circuit 120 may output the output signal of the first input signal-inverting circuit 110 at the ground voltage VSS level. Thus, the first input node N_inA is at the external voltage VDD level. The second input node N_inB is at the ground voltage VSS level.

The first signal transmission circuit 210 may transmit the low voltage level of the input node among the first and second input nodes N_inA and N_inB to the first latch circuit 220. Therefore, the first signal transmission circuit 210 may transmit the voltage level of the second input node N_inB to the first latch circuit 220.

Particularly, the first signal transmission circuit 210 may include the first and second transistors N1 and N2. Because the external voltage VDD is applied to the gates of the first and second transistors N1 and N2, turn-on of the first and second transistors N1 and N2 may be determined in accordance with the voltage level inputted into the sources. When the voltage level of the first input node N_inA is at the external voltage VDD level and the voltage level of the second input node N_inB is at the ground voltage VSS level, the first transistor N1 may be turned-off and the second transistor N2 may be turned-on. Thus, the voltage level of the second input node N_inB may be transmitted to the first latch circuit 220 through the turned-on second transistor N2.

When the first latch circuit 220 receives the ground voltage VSS level of the second input node N_inB, the third transistor P1 may be turned-on so that the voltage level of the first output node N_outA may change to the pumping voltage VPP level.

When the voltage level of the first output node N_outA changes to the pumping voltage VPP level, the first output circuit 410 may output the first output signal OUT_sA having the ground voltage VSS level.

As mentioned above, when the input signal IN_s is at the low level, the first input node N_inA may change to the external voltage VDD level and the second input node N_inB may change to the ground voltage VSS level.

The second signal transmission circuit 310 may transmit the high voltage level of the input node among the first and second input nodes N_inA and N_inB to the second latch circuit 320. Therefore, the second signal transmission circuit 310 may transmit the voltage level of the first input node N_inA to the second latch circuit 320.

Particularly, the second signal transmission circuit 310 may include the fifth and sixth transistors P3 and P4. Because the ground voltage VSS may be applied to the gates of the fifth and sixth transistors P3 and P4, turn-on of the fifth and sixth transistors P3 and P4 may be determined in accordance with the voltage level inputted into the sources. When the voltage level of the first input node N_inA is at the external voltage VDD level and the voltage level of the second input node N_inB is at the ground voltage VSS level, the fifth transistor P3 may be turned-on and the sixth transistor P4 may be turned-off. Thus, the voltage level of the first input node N_inA may be transmitted to the second latch circuit 320 through the turned-on fifth transistor P3.

When the second latch circuit 320 receives the external voltage VDD level of the first input node N_inA, the eighth transistor N4 may be turned-on and the seventh transistor N3 may be turned-off. The second output node N_outB may be connected with the first input node N_inA so that the voltage level of the second output node N_outB may change to the external voltage VDD level.

When the voltage level of the second output node N_outB changes to the external voltage VDD level, the second output circuit 420 may output the second output signal OUT_sB having the negative voltage VNN level.

According to an example of the embodiments, the semiconductor device may output the output signals having the different maximum voltage levels and the different minimum voltage levels in response to the single input signal IN_s. Further, because the external voltage and the ground voltage may be applied to the gates and the sources of the turned-off first transistor N1 or second transistor N2 and the sources of the turned-off fifth transistor P3 or sixth transistor P4, respectively, stresses between the gate and the source, and between the drain and the source in the transistors of the first and second signal transmission circuits 210 and 310 may be reduced. Furthermore, the turn-on and the turn-off of the transistors of the first and second signal transmission circuits 210 and 310 may be controlled by the voltage level changes of the drains and sources, respectively, not the gates.

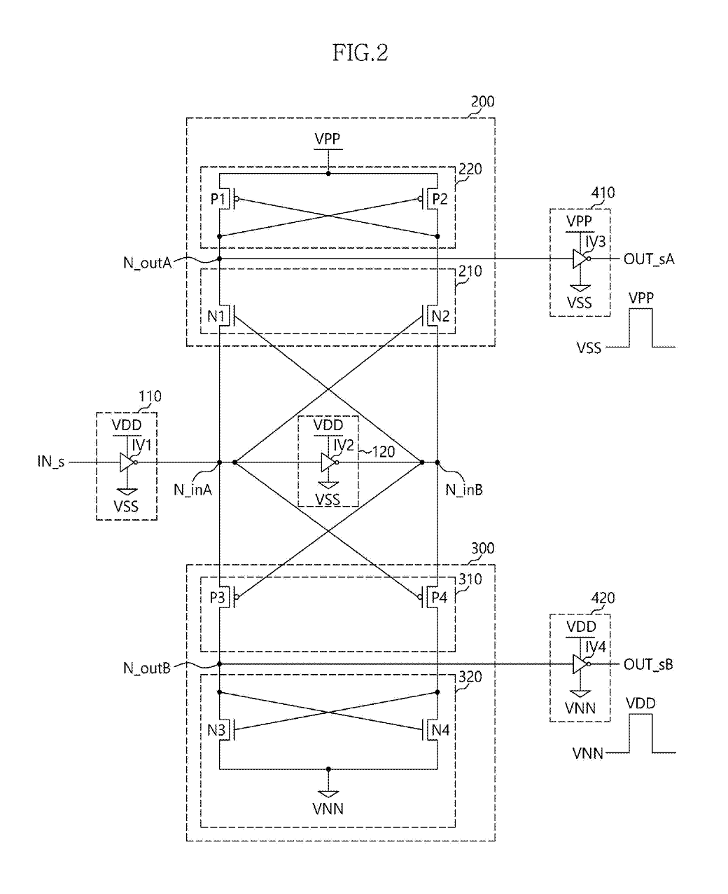

FIG. 2 is a circuit diagram illustrating a semiconductor device in accordance with examples of embodiments.

Referring to FIG. 2, in an embodiment, for example, a semiconductor device may include a first input signal-inverting circuit 2110, a second input signal-inverting circuit 2120, a first level-shifting circuit 2200, a second level-shifting circuit 2300, a first output circuit 2410 and a second output circuit 2420.

The first input signal-inverting circuit 2110 may invert an input signal IN_s. The first input signal-inverting circuit 2110 may output the inverted input signal IN_s to a first input node N_inA.

The first input signal-inverting circuit 2110 may include a first inverter IV1. The first inverter IV1 may receive an external voltage VDD and a ground voltage VSS. Thus, a maximum voltage level of the output signal from the first inverter IV1 may correspond to the external voltage VDD. A minimum voltage level of the output signal from the first inverter IV1 may correspond to the ground voltage VSS.

The second input signal-inverting circuit 2120 may invert the output signal from the first input signal-inverting circuit 2110. The second input signal-inverting circuit 2120 may output the inverted output signal to a second input node N_inB.

The second input signal-inverting circuit 2120 may include a second inverter IV2. The second inverter IV2 may receive the external voltage VDD and the ground voltage VSS. Thus, a maximum voltage level of the output signal from the second inverter IV2 may correspond to the external voltage VDD. A minimum voltage level of the output signal from the second inverter IV2 may correspond to the ground voltage VSS.

The first level-shifting circuit 2200 may be configured to determine a voltage level of a first output node N_outA in response to the voltage levels of the first and second input nodes N_inA and N_inB. The first level-shifting circuit 2200 may receive a pumping voltage VPP. The first level-shifting circuit 2200 may be operated by the pumping voltage VPP. For example, when the voltage level of the first input node N_inA is at the external voltage VDD level and the voltage level of the second input node N_inB is at the ground voltage VSS level, the first level-shifting circuit 2200 may increase the voltage level of the first output node N_outA to the pumping voltage VPP. In contrast, when the voltage level of the first input node N_inA is at the ground voltage VSS and the voltage level of the second input node N_inB is at the external voltage VDD, the first level-shifting circuit 2200 may provide the voltage level of the first output node N_outA with the ground voltage VSS.

The first level-shifting circuit 2200 may include a first signal transmission circuit 2210 and a first latch circuit 2220.

The first signal transmission circuit 2210 may transmit any one of the voltage levels of the first and second input nodes N_inA and N_inB to the first latch circuit 2220 in response to the voltage levels of the first and second input nodes N_inA and N_inB. For example, the first signal transmission circuit 2210 may transmit a voltage of an input node having a relatively low voltage level among the voltage levels of the first and second input nodes N_inA and N_inB to the first latch circuit 2220. Particularly, when the voltage level of the first input node N_inA is at the ground voltage VSS level and the voltage level of the second input node N_inB is at the external voltage VDD level, the first signal transmission circuit 2210 may transmit the voltage level of the first input node N_intA to the first latch circuit 2220. In contrast, when the voltage level of the first input node N_inA is at the external voltage VDD level and the voltage level of the second input node N_inB is at the ground voltage VSS level, the first signal transmission circuit 2210 may transmit the voltage level of the second input node N_inB to the first latch circuit 2220.

The first signal transmission circuit 2210 may include a first transistor N1 and a second transistor N2. The first transistor N1 may include a gate to which the output signal from the second input signal-inverting circuit 2120 may be applied, a source connected with the first input node N_inA, and a drain connected with the first latch circuit 2220. The second transistor N2 may include a gate to which the output signal from the first input signal-inverting circuit 2110 may be applied, a source connected with the second input node N_inB, and a drain connected with the first latch circuit 2220.

The first latch circuit 2220 may be configured to determine the voltage level of the first output node N_outA in response to any one of the voltage levels of the first and second input nodes N_inA and N_inB transmitted from the first signal transmission circuit 2210. For example, when the ground voltage VSS of the first input node N_inA is transmitted from the first signal transmission circuit 2210, the first latch circuit 2220 may provide the voltage level of the first output node N_outA with the ground voltage VSS. In contrast, when the ground voltage VSS of the second input node N_inB is transmitted from the first signal transmission circuit 2210, the first latch circuit 2220 may provide the voltage level of the first output node N_outA with the pumping voltage VPP.

The first latch circuit 2220 may include a third transistor P1 and a fourth transistor P2. The third transistor P1 may include a gate connected with the second transistor N2 of the first signal transmission circuit 2210, a source to which the pumping voltage VPP may be applied, and a drain connected with the first transistor N1 of the first signal transmission circuit 2210. The fourth transistor P2 may include a gate connected with the first transistor N1 of the first signal transmission circuit 2210, a source to which the pumping voltage VPP may be applied, and a drain connected with the second transistor N2 of the first signal transmission circuit 2210.

The second level-shifting circuit 2300 may be configured to determine a voltage level of a second output node N_outB in response to the voltage levels of the first and second input nodes N_inA and N_inB. The second level-shifting circuit 2300 may receive a negative voltage VNN. The second level-shifting circuit 2300 may be operated by the negative voltage VNN. For example, when the voltage level of the first input node N_inA is at the external voltage VDD level and the voltage level of the second input node N_inB is at the ground voltage VSS, the second level-shifting circuit 2300 may increase the voltage level of the second output node N_outB to the external voltage VDD. In contrast, when the voltage level of the first input node N_inA is at the ground voltage VSS level and the voltage level of the second input node N_inB is at the external voltage VDD level, the second level-shifting circuit 2300 may decrease the voltage level of the second output node N_outB to the negative voltage VNN.

The second level-shifting circuit 2300 may include a second signal transmission circuit 2310 and a second latch circuit 2320.

The second signal transmission circuit 2310 may transmit any one of the voltage levels of the first and second input nodes N_inA and N_inB to the second latch circuit 2320 in response to the voltage levels of the first and second input nodes N_inA and N_inB. For example, the second signal transmission circuit 2310 may transmit a voltage of an input node having a relatively high voltage level among the voltage levels of the first and second input nodes N_inA and N_inB to the second latch circuit 2320. Particularly, when the voltage level of the first input node N_inA is at the ground voltage VSS level and the voltage level of the second input node N_inB is at the external voltage VDD level, the second signal transmission circuit 2310 may transmit the voltage level of the second input node N_inB to the second latch circuit 2320. In contrast, when the voltage level of the first input node N_inA is at the external voltage VDD level and the voltage level of the second input node N_inB is at the ground voltage VSS level, the second signal transmission circuit 2310 may transmit the voltage level of the first input node N_inA to the second latch circuit 2320.

The second signal transmission circuit 2310 may include a fifth transistor P3 and a sixth transistor P4. The fifth transistor P3 may include a gate to which the output signal from the second input signal-inverting circuit 2120 may be applied, a source connected with the first input node N_inA, and a drain connected with the second latch circuit 2320. The sixth transistor P4 may include a gate to which the output signal from the first input signal-inverting circuit 2110 may be applied, a source connected with the second input node N_inB, and a drain connected with the second latch circuit 2320.

The second latch circuit 2320 may be configured to determine the voltage level of the second output node N_outB in response to any one of the voltage levels of the first and second input nodes N_inA and N_inB transmitted from the second signal transmission circuit 2310. For example, when the external voltage VDD of the first input node N_inA is transmitted from the second signal transmission circuit 2310, the second latch circuit 2320 may provide the voltage level of the second output node N_outB with the external voltage VDD. In contrast, when the external voltage VDD of the second input node N_inB is transmitted from the second signal transmission circuit 2310, the second latch circuit 2320 may provide the voltage level of the second output node N_outB with the negative voltage VNN.

The second latch circuit 2320 may include a seventh transistor N3 and an eighth transistor N4. The seventh transistor N3 may include a gate connected with the sixth transistor P4 of the second signal transmission circuit 2310, a source to which the negative voltage VNN may be applied, and a drain connected with the fifth transistor P3 of the second signal transmission circuit 2310. The eighth transistor N4 may include a gate connected with the fifth transistor P3 of the second signal transmission circuit 2310, a source to which the negative voltage VNN may be applied, and a drain connected with the sixth transistor P4 of the second signal transmission circuit 2310.

The first output circuit 2410 may output a first output signal OUT_sA in response to the voltage level of the first output node N_outA. For example, when the voltage level of the first output node N_outA is at the voltage level of the ground voltage VSS, the first output circuit 2410 may output the first output signal OUT_sA having the level of the pumping voltage VPP. In contrast, when the voltage level of the first output node N_outA is at the voltage level of the pumping voltage VPP, the first output circuit 2410 may output the first output signal OUT_sA having the level of the ground voltage VSS.

The first output circuit 2410 may include a third inverter IV3. The third inverter IV3 may invert the voltage level of the first output node N_outA to output the first output signal OUT_sA. The pumping voltage VPP and the ground voltage VSS may be applied to the third inverter IV3. Thus, the third inverter IV3 may be operated by the pumping voltage VPP and the ground voltage VSS.

The second output circuit 2420 may output a second output signal OUT_sB in response to the voltage level of the second output node N_outB. For example, when the voltage level of the second output node N_outB is at the voltage level of the negative voltage VNN, the second output circuit 2420 may output the second output signal OUT_sB having the level of the external voltage VDD. In contrast, when the voltage level of the second output node N_outB is at the voltage level of the external voltage VDD, the second output circuit 2420 may output the second output signal OUT_sB having the level of the negative voltage VNN.

The second output circuit 2420 may include a fourth inverter IV4. The fourth inverter IV4 may invert the voltage level of the second output node N_outB to output the second output signal OUT_sB. The external voltage VDD and the negative voltage VNN may be applied to the fourth inverter IV4. Thus, the fourth inverter IV4 may be operated by the external voltage VDD and the negative voltage VNN.

Hereinafter, operations of the semiconductor device in accordance with an example of an embodiment with be discussed below.

When the input signal IN_s is at a high level, the first input signal-inverting circuit 2110 may output the output signal at the ground voltage VSS level. The second input signal-inverting circuit 2120 may output the output signal of the first input signal-inverting circuit 2110 at the external voltage VDD level. Thus, the first input node N_inA may be at the ground voltage VSS level. The second input node N_inB may be at the external voltage VDD level.

The first signal transmission circuit 2210 may transmit the low voltage level of the input node among the first and second input nodes N_inA and N_inB to the first latch circuit 2220. Therefore, the first signal transmission circuit 2210 may transmit the voltage level of the first input node N_inA to the first latch circuit 2220.

Particularly, the first signal transmission circuit 2210 may include the first and second transistors N1 and N2. Because the first transistor N1 may include the gate into which the output signal from the second input signal-inverting circuit 2120 may be inputted and the source into which the output signal from the first input signal-inverting circuit 2110 may be inputted, and the second transistor N2 may include the gate into which the output signal from the first input signal-inverting circuit 2110 and the source into which the output signal from the second input signal-inverting circuit 2120, any one of the first and second transistors N1 and N2 may be turned-on in accordance with the voltage levels of the input signal IN_s. When the voltage level of the first input node N_inA is at the ground voltage VSS level and the voltage level of the second input node N_inB is at the external voltage VDD level, the first transistor N1 may be turned-on and the second transistor N2 may be turned-off. Thus, the voltage level of the first input node N_inA may be transmitted to the first latch circuit 2220 through the turned-on first transistor N1.

When the first latch circuit 2220 receives the ground voltage VSS level of the first input node N_inA, the fourth transistor P2 may be turned-on and the third transistor P1 may be turned-off. Thus, the first output node N_outA may be connected with the first input node N_inA so that the voltage level of the first output node N_outA may change to the ground voltage VSS level.

When the voltage level of the first output node N_outA changes to the ground voltage VSS level, the first output circuit 2410 may output the first output signal OUT_sA having the pumping voltage VPP level.

As mentioned above, when the input signal IN_s is at the high level, the first input node N_inA may change to the ground voltage VSS level and the second input node N_inB may change to the external voltage VDD level.

The second signal transmission circuit 2310 may transmit the high voltage level of the input node among the first and second input nodes N_inA and N_inB to the second latch circuit 2320. Therefore, the second signal transmission circuit 2310 may transmit the voltage level of the second input node N_inB to the second latch circuit 2320.

Particularly, the second signal transmission circuit 2310 may include the fifth and sixth transistors P3 and P4. Because the fifth transistor P3 may include the gate into which the output signal from the second input signal-inverting circuit 2120 may be inputted and the source into which the output signal from the first input signal-inverting circuit 2110 may be inputted, and the sixth transistor P4 may include the gate into which the output signal from the first input signal-inverting circuit 2110 and the source into which the output signal from the second input signal-inverting circuit 2120, turn-on of the fifth and sixth transistors P3 and P4 may be determined in accordance with the voltage level inputted into the sources. When the voltage level of the first input node N_inA is at the ground voltage VSS level and the voltage level of the second input node N_inB is at the external voltage VDD level, the sixth transistor P4 may be turned-on and the fifth transistor P3 may be turned-off. Thus, the voltage level of the second input node N_inB may be transmitted to the second latch circuit 2320 through the turned-on sixth transistor P4.

When the second latch circuit 2320 receives the external voltage VDD level of the second input node N_inB, the seventh transistor N3 may be turned-on so that the voltage level of the second output node N_outB may change to the negative voltage VNN level.

When the voltage level of the second output node N_outB changes to the negative voltage VNN level, the second output circuit 2420 may output the second output signal OUT_sB having the external voltage VDD level.

When the input signal IN_s is at the low level, the first input signal-inverting circuit 2110 may output the output signal of the external voltage VDD level. The second input signal-inverting circuit 2120 may output the output signal of the ground voltage VSS level. Thus, the first input node N_inA may be the external voltage VDD level. The second input node N_inB may be the ground voltage VSS level.

The first signal transmission circuit 2210 may transmit the low voltage level of the input node among the first and second input nodes N_inA and N_inB to the first latch circuit 2220. Therefore, the first signal transmission circuit 2210 may transmit the voltage level of the second input node N_inB to the first latch circuit 2220.

Particularly, the first signal transmission circuit 2210 may include the first and second transistors N1 and N2. When the voltage level of the first input node N_inA, i.e., the voltage level of the output signal from the first input signal-inverting circuit 2110 is at the external voltage VDD level and the voltage level of the second input node N_inB, i.e., the voltage level of the output signal from the second input signal-inverting circuit 2120 is at the ground voltage VSS level, the first transistor N1 may be turned-off and the second transistor N2 may be turned-on. Thus, the voltage level of the second input node N_inB may be transmitted to the first latch circuit 2220 through the turned-on second transistor N2.

When the first latch circuit 2220 receives the ground voltage VSS level of the second input node N_inB, the third transistor P3 may be turned-on so that the voltage level of the first output node N_outA may change to the pumping voltage VPP level.

When the voltage level of the first output node N_outA changes to the pumping voltage VPP level, the first output circuit 2410 may output the first output signal OUT_sA having the ground voltage VSS level.

As mentioned above, when the input signal IN_s is at the low level, the first input node N_inA may change to the external voltage VDD level and the second input node N_inB may change to the ground voltage VSS level.

The second signal transmission circuit 2310 may transmit the high voltage level of the input node among the first and second input nodes N_inA and N_inB to the second latch circuit 2320. Therefore, the second signal transmission circuit 2310 may transmit the voltage level of the first input node N_inA to the second latch circuit 2320.

Particularly, the second signal transmission circuit 2310 may include the fifth and sixth transistors P3 and P4. Because the fifth transistor P3 may include the gate into which the output signal from the second input signal-inverting circuit 2120 may be inputted and the source into which the output signal from the first input signal-inverting circuit 2110 may be inputted, and the sixth transistor P4 may include the gate into which the output signal from the first input signal-inverting circuit 2110 and the source into which the output signal from the second input signal-inverting circuit 2120, turn-on of the fifth and sixth transistors P3 and P4 may be determined in accordance with the voltage level inputted into the sources. When the voltage level of the first input node N_inA is at the external voltage VDD level and the voltage level of the second input node N_inB is at the ground voltage VSS level, the fifth transistor P3 may be turned-on and the sixth transistor P4 may be turned-off. Thus, the voltage level of the first input node N_inA may be transmitted to the second latch circuit 2320 through the turned-on fifth transistor P3.

When the second latch circuit 2320 receives the external voltage VDD level of the first input node N_inA, the eighth transistor N4 may be turned-on and the seventh transistor N3 may be turned-off. The second output node N_outB may be connected with the first input node N_inA so that the voltage level of the second output node N_outB may change to the external voltage VDD level.

When the voltage level of the second output node N_outB changes to the external voltage VDD level, the second output circuit 2420 may output the second output signal OUT_sB having the negative voltage VNN level.

According to an example of the embodiments, the semiconductor device may output the output signals having the different maximum voltage levels and the different minimum voltage levels in response to the single input signal IN_s. Further, because the external voltage and the ground voltage may be applied to the gates and the sources of the turned-off first transistor N1 or second transistor N2 and the sources of the turned-off fifth transistor P3 or sixth transistor P4, respectively, stresses applied to the transistors of the first and second signal transmission circuits 2210 and 2310 may be reduced.

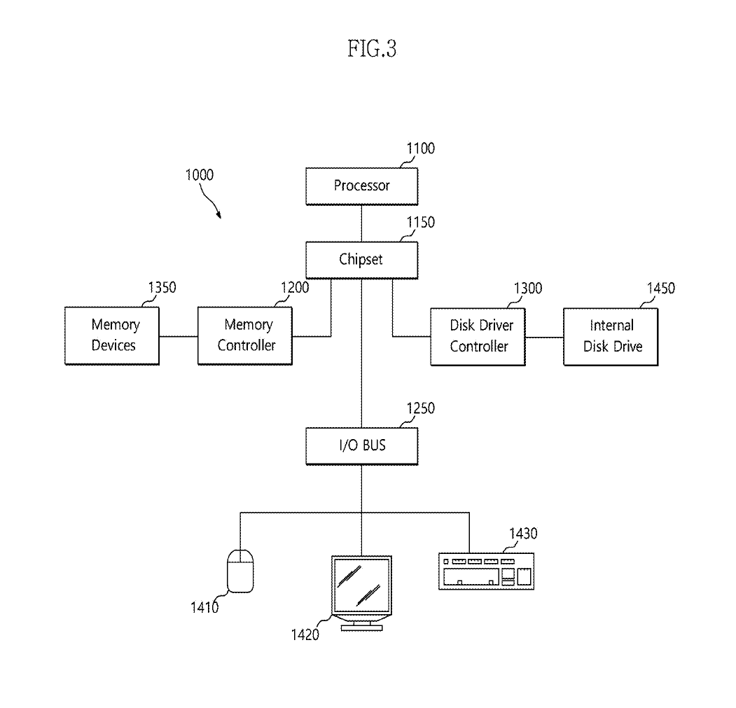

The semiconductor devices and or methods as discussed above (see FIGS. 1-2) are particular useful in the design of other memory devices, processors, and computer systems. For example, referring to FIG. 3, a block diagram of a system employing a semiconductor device and or method in accordance with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one semiconductor device and or method as discussed above with reference to FIGS. 1-2. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one semiconductor device and or method as discussed above with relation to FIGS. 1-2, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 3 is merely one example of a system employing the semiconductor devices and or methods as discussed above with relation to FIGS. 1-2. In alternate embodiments, such as, for example but not limited to, cellular phones or digital cameras, the components may differ from the embodiments illustrated in FIG. 3.

The above embodiments of the present disclosure are illustrative and not limitative. Various alternatives and equivalents are possible. The examples of the embodiments are not limited by the embodiments described herein. Nor is the present disclosure limited to any specific type of semiconductor device. Other additions, subtractions, or modifications are obvious in view of the present disclosure and are intended to fall within the scope of the appended claims.

What is claimed is:

1. A semiconductor device comprising:
a first input signal-inverting circuit configured to invert and output an input signal;
a second input signal-inverting circuit configured to invert and output an output signal from the first input signal-inverting circuit;
a first level-shifting circuit configured to determine a voltage level of a first output node in response to the output signals from the first and second input signal-inverting circuits; and
a second level-shifting circuit configured to determine a voltage level of a second output node in response to the output signals from the first and second input signal-inverting circuits.

2. The semiconductor device of claim 1, wherein a maximum voltage level and a minimum voltage level of the first output node are different from a maximum voltage level and a minimum voltage level of the second output node, respectively.

3. The semiconductor device of claim 1, wherein each of the first and second input signal-inverting circuits comprises an inverter operated by an external voltage and a ground voltage.

4. The semiconductor device of claim 1, wherein the first level-shifting circuits comprises:
a signal transmission circuit configured to transmit the output signal from any one of the first and second input signal-inverting circuits in response to the output signals from the first and second input signal-inverting circuits; and
a latch circuit configured to determine the voltage level of the first output node in response to a voltage level of an output signal from the signal transmission circuit.

5. The semiconductor device of claim 4, wherein the signal transmission circuit transmits the output signal having a low voltage level of the output signals from the first and second input signal-inverting circuits.

6. The semiconductor device of claim 5, wherein the signal transmission circuit comprises:
a first transistor including a gate to which an external voltage is applied, a source into which the output signal from the first input signal-inverting circuit is inputted, and a drain connected with the latch circuit; and
a second transistor including a gate to which the external voltage is applied, a source into which the output signal from the second input signal-inverting circuit is inputted, and a drain connected with the latch circuit.

7. The semiconductor device of claim 5, wherein the signal transmission circuit comprises:
a first transistor including a gate into which the output signal from the second input signal-inverting circuit is inputted, a source into which the output signal from the first input signal-inverting circuit is inputted, and a drain connected with the latch circuit; and
a second transistor including a gate into which the output signal from the first input signal-inverting circuit is inputted, a source into which the output signal from the second input signal-inverting circuit is inputted, and a drain connected with the latch circuit.

8. The semiconductor device of claim 4, wherein the latch circuit is configured to receive a pumping voltage and provide the first output node with any one of the voltage levels of the pumping voltage and the ground voltage in response to the voltage level of the output signal from the signal transmission circuit.

9. The semiconductor device of claim 1, wherein the second level-shifting circuits comprises:
a signal transmission circuit configured to transmit the output signal from any one of the first and second input signal-inverting circuits in response to the output signals from the first and second input signal-inverting circuits; and
a latch circuit configured to determine the voltage level of the second output node in response to a voltage level of a signal from the signal transmission circuit.

10. The semiconductor device of claim 9, wherein the signal transmission circuit transmits the output signal having a high voltage level of the output signals from the first and second input signal-inverting circuits.

11. The semiconductor device of claim 10, wherein the signal transmission circuit comprises:
a first transistor including a gate to which a ground voltage is applied, a source into which the output signal from the first input signal-inverting circuit is inputted, and a drain connected with the latch circuit; and
a second transistor including a gate to which the ground voltage is applied, a source into which the output signal from the second input signal-inverting circuit is inputted, and a drain connected with the latch circuit.

12. The semiconductor device of claim 9, wherein the signal transmission circuit comprises:
a first transistor including a gate into which the output signal from the second input signal-inverting circuit is inputted, a source into which the output signal from the first input signal-inverting circuit is inputted, and a drain connected with the latch circuit; and
a second transistor including a gate into which the output signal from the first input signal-inverting circuit is inputted, a source into which the output signal from the second input signal-inverting circuit is inputted, and a drain connected with the latch circuit.

13. The semiconductor device of claim 9, wherein the latch circuit is configured to receive a negative voltage and provide the second output node with any one of the voltage levels of the negative voltage and the external voltage in response to the voltage level of the output signal from the signal transmission circuit.

14. The semiconductor device of claim 1, further comprising:
a first output circuit configured to output an output signal having a voltage level of any one of a pumping voltage and a ground voltage in response to a voltage level of the first output node; and
a second output circuit configured to output an output signal having a voltage level of any one of a negative voltage and an external voltage in response to a voltage level of the second output node.

15. The semiconductor device of claim 14, wherein the first output circuit comprises a first inverter operated by the pumping voltage and the ground voltage, and the second output circuit comprises a second inverter operated by the external voltage and the negative voltage.

16. A method of operating a semiconductor device, the method comprising:
inverting a first input signal and outputting a first resultant signal;
inverting the resultant signal and outputting a second resultant signal;
determining a voltage level of a first output node in response to the first and second resultant signals; and
determining a voltage level of a second output node in response to the first and second resultant signals.

17. The method of claim 16, wherein a maximum voltage level and a minimum voltage level used to determine the voltage level of the first output node is different from a maximum voltage level and a minimum voltage level used to determine the voltage level of the second output node.
